(19) United States
(12) Patent Application Publication
(10) Pub. No.: US 2024/0361545 A1
(43) Pub. Date: Oct. 31, 2024

(54) METAL FINGER STRUCTURE IN INPUT/OUTPUT OPENING OF IC CHIP

(71) Applicant: GlobalFoundries U.S. Inc., Malta, NY (US)

(72) Inventors: Zhuojie Wu, Port Chester, NY (US); Erdem Kaltalioglu, Newburgh, NY (US)

(21) Appl. No.: 18/307,151

(22) Filed: Apr. 26, 2023

(51) Int. Cl. G02B 6/42

(52) U.S. Cl. CPC G02B 6/4248; H01L 23/5283; H01L 23/53295; H01L 23/564

(57) ABSTRACT

A structure includes an integrated circuit (IC) chip including a substrate. An input/output (I/O) opening extends inwardly from an exterior surface of the IC chip. A metal finger structure protrudes partly into the I/O opening, and outer surfaces of the metal finger structure are covered by a moisture barrier. The metal finger structure may provide stress-relief by removing attacking surfaces for stress in the I/O opening and/or otherwise reduces stress, such as film stresses, to reduce damage to the moisture barrier and improve reliability compared to conventional devices.

### BACKGROUND

The present disclosure relates to integrated circuits and, more particularly, to a structure including a metal finger structure protruding partly into an input/output opening of an integrated circuit (IC) chip.

IC chips can fail or be damaged when moisture enters the structure, e.g., within a guard ring. Photonics integrated circuit (PIC) chips are especially prone to moisture ingress due to input/output openings in their guard ring used, for example, to connect to external electrical or photonics components. Moisture barriers, such as a thin dielectric layer of silicon nitride (SiN), are used around the chip periphery and the input/output openings.

### SUMMARY

All aspects, examples and features mentioned below can be combined in any technically possible way.

An aspect of the disclosure provides a structure, comprising: an integrated circuit (IC) chip including a substrate; an input/output (I/O) opening extending inwardly from an exterior surface of the IC chip; and a metal finger structure protruding partly into the I/O opening, wherein outer surfaces of the metal finger structure are covered by a moisture barrier.

An aspect of the disclosure provides a structure, comprising: an integrated circuit (IC) chip including a substrate; an input/output (I/O) opening extending inwardly from an exterior surface of the IC chip; a metal guard ring extending around an exterior of the substrate; and a metal guard ring finger structure coupled to the metal guard ring and protruding partly into the I/O opening and extending vertically over at least one via layer and at least one metal wire layer of the IC chip, wherein outer surfaces of the metal guard ring finger structure are covered by a moisture barrier, wherein the metal guard ring finger structure has a stair-stepped outer surface.

An aspect of the disclosure provides a method, comprising: forming a metal guard ring extending around an exterior of a substrate of an integrated circuit (IC) chip, including forming a metal guard ring finger structure coupled to the metal guard ring, wherein the metal guard ring finger structure protrudes partly into an input/output opening; and forming a moisture barrier over outer surfaces of the metal guard ring finger structure and extending around the exterior of the substrate of the IC chip adjacent the metal guard ring.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a top-down view of a structure and IC chip including a metal guard ring finger structure, according to embodiments of the disclosure;

FIG. 2 shows a cross-sectional view of the structure and IC chip along view line 2-2 in FIG. 1;

FIG. 3 shows a cross-sectional view of the structure and IC chip along view line 3-3 in FIG. 1;

FIG. 4 shows an enlarged top-down view of a metal guard ring finger structure from the view box in FIG. 1, according to embodiments of the disclosure;

FIG. 5 shows a cross-sectional view of a metal guard ring finger structure along view line A-A in FIG. 4, according to embodiments of the disclosure;

FIG. 6 shows a cross-sectional view of a metal guard ring finger structure along view line B-B in FIG. 4, according to embodiments of the disclosure;

FIG. 7 shows an end view of a metal guard ring finger structure along view line C-C in FIG. 4, according to embodiments of the disclosure;

FIG. 8 shows a cross-sectional view of a metal guard ring finger structure along view line D-D in FIG. 4, according to embodiments of the disclosure;

FIG. 9 shows a cross-sectional view of a metal guard ring finger structure along view line A-A in FIG. 4, according to another embodiment of the disclosure;

FIG. 10 shows a cross-sectional view of a metal guard ring finger structure along view line B-B in FIG. 4, according to another embodiment of the disclosure;

FIG. 11 shows a top-down view of a structure and IC chip including a metal guard ring finger structure, according to other embodiments of the disclosure;

FIG. 12 shows a top-down view of a structure and IC chip including a metal guard ring finger structure, according to additional embodiments of the disclosure; and

FIG. 13 shows a top-down view of a structure and IC chip including a metal guard ring finger structure, according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which are shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure include a structure including an integrated circuit (IC) chip including a substrate. An input/output (I/O) opening extends inwardly from an exterior surface of the IC chip. A metal guard ring finger structure protrudes partly into the I/O opening, and outer surfaces of the metal guard ring finger structure are covered by a moisture barrier. The finger structure may provide stress-relief by removing attacking surfaces for stress in the I/O opening and/or otherwise reduces stress, such as film stresses, to reduce damage to the moisture barrier and improve reliability compared to conventional devices.

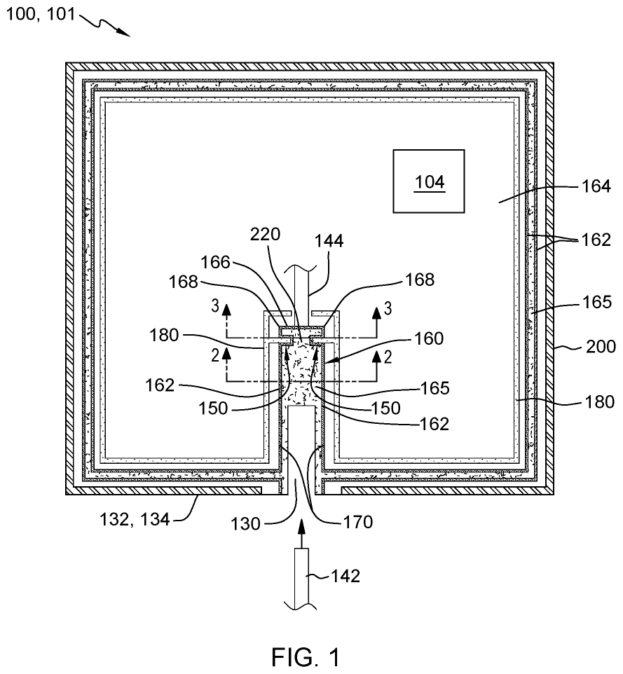

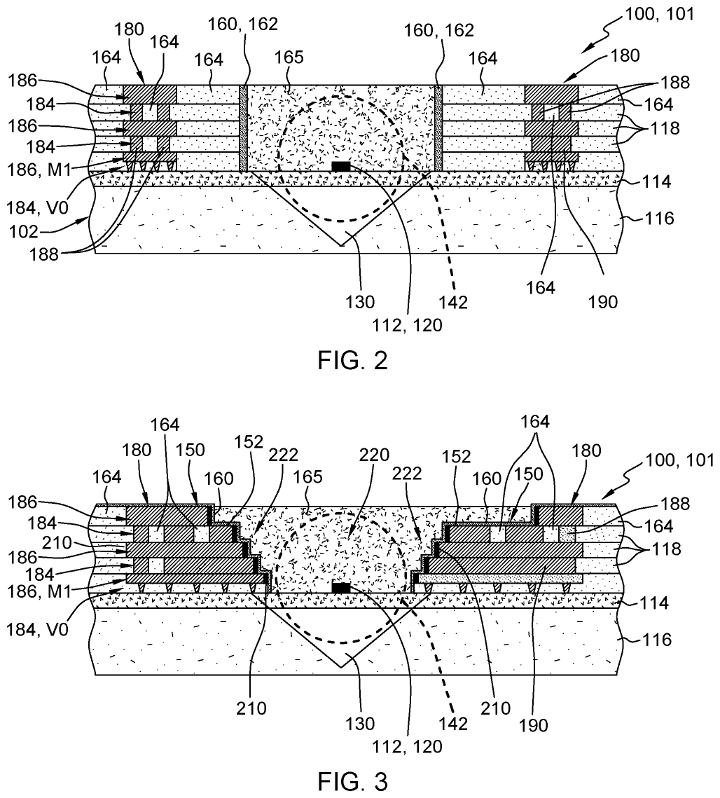

FIG. 1 shows a top-down view of a structure 100, FIG. 2 shows a cross-sectional view along view line 2-2 in FIG. 1, and FIG. 3 shows a cross-sectional view along view line 3-3 in FIG. 1, according to embodiments of the disclosure. (Note, in the cross-sectional views in FIGS. 2 and 3, a dielectric layer 164 is shown with shading; however, in the top-down drawings herein, e.g., FIG. 1, dielectric layer 164 is shown white for clarity purposes).

With reference to FIGS. 1-3, structure 100 includes an integrated circuit (IC) chip 101 including a substrate 102. Substrate 102 can be broadly defined to include a semiconductor substrate upon which active circuitry 104 and other structures are formed. Other structures may include but are not limited to: middle-of-line (MOL) and/or back-end-of-line (BEOL) interconnects that electrically interconnect active circuitry 104 and/or photonic components, and/or related packaging layers over BEOL interconnects. Substrate 102 can be in the form of, for example, a bulk semiconductor or a semiconductor-on-insulator (SOI) substrate (latter shown). In one non-limiting example, as shown in FIGS. 2 and 3, where an SOI substrate is used, substrate 102 may include a semiconductor-on-insulator (SOI) layer 112 over a buried insulator layer 114 over a base semiconductor layer 116. SOI layer 112 and base semiconductor layer 116 may include silicon, silicon germanium or other semiconductor materials. Buried insulator layer 114 may include any appropriate dielectric such as but not limited to silicon dioxide. As also shown in FIGS. 2 and 3, various MOL and/or BEOL interconnect layers 118 (hereafter “interconnect layers 118”) that electrically interconnect active circuitry 104 and/or photonic components may be provided over substrate 102. Individual via layers 184 and metal layer 186 of interconnect layers 118 are also shown for later reference.

Structure 100 may include any now known or later developed integrated circuit or photonics integrated circuit including any variety of active circuitry 104 that may experience moisture ingress. Active circuitry 104 can include any form of circuity including but not limited to: logic, memory, and/or photonics. Moisture ingress into structure 100 and active circuitry 104 can damage the physical structure of, for example, active circuitry 104, interconnect layers, photonics, etc.

With continuing reference to FIGS. 1-3, for purposes of description, structure 100 and, in particular, IC chip 101 is illustrated as a photonics integrated circuit (PIC) chip. For example, in FIGS. 2 and 3, SOI layer 112 is shown to include silicon edge couplers 120 which may couple to, for example, internal optical waveguides 144 (see e.g., FIG. 1). A center of an external component 142, e.g., an optical fiber, may be offset from silicon edge coupler 120, as shown in FIGS. 2 and 3. For example, the center of an optical fiber may be about 0.8-1.0 micrometers (μm) above silicon edge coupler 120, or the center of the optical fiber may be aligned with silicon edge coupler 120, e.g., with zero offset. It will be recognized that other structure(s), such as a silicon nitride edge coupler (not shown) above silicon edge coupler 120, may also be present to assist in coupling light from the optical fiber to an internal optical waveguide 144 on IC chip 101. (It is recognized by those with skill in the art that SOI layer 112 may also be used for a wide variety of other devices, such as transistors of active circuitry 104. Further, optical waveguides, such as silicon nitride waveguides, can be provided in other layers of structure 100 and IC chip 101.)

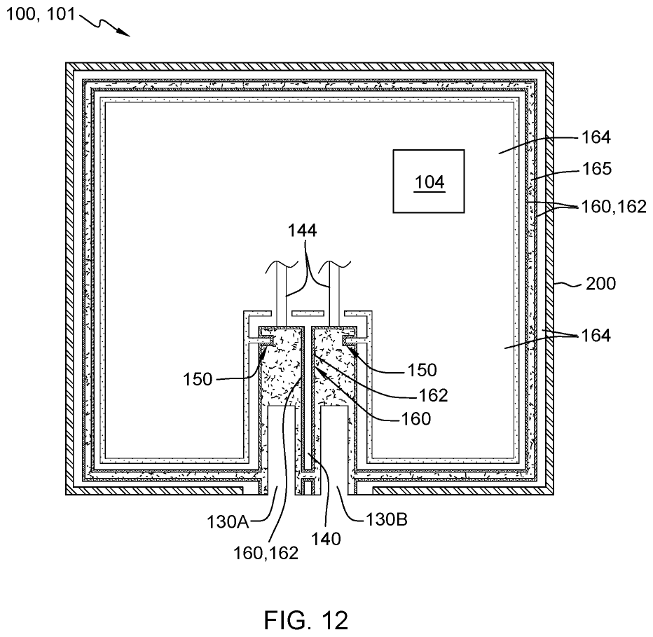

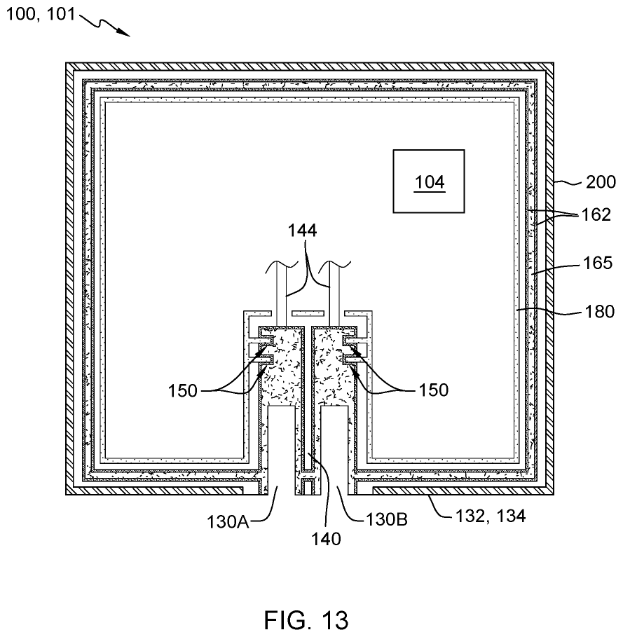

Certain IC structures and many PIC structures present a heightened risk of moisture ingress because they include one or more input/output (I/O) openings 130 that present moisture ingress paths through which moisture can pass through a moisture barrier 160. Structure 100 includes at least one I/O opening 130 extending inwardly from an exterior surface 132 of IC chip 101. In FIG. 1, exterior surface 132 of IC chip 101 includes an edge 134 of IC chip 101. As shown in FIGS. 12 and 13, more than one I/O opening 130 may be possible. In this case, each I/O opening 130 is separated from an adjacent I/O opening 130 by a wall 140, e.g., including one or more interlayer dielectric (ILD) layers of interconnect layers 118. I/O openings 130 are provided to allow connection of external components 142 (FIGS. 1-3 only for clarity), such as external photonics components or external electronic components. For purposes that will be further described herein, structure 100 also includes a metal finger structure 150 protruding partly into I/O opening(s) 130.

External components 142 in the form of electrical devices in I/O openings 130 can take any now known or later developed form. External components 142 in the form of optical components in I/O openings 130 can take any now known or later developed form such as but not limited to: an optical fiber; an external optical component such as a laser; an optical waveguide of, for example, silicon, silicon nitride, aluminum nitride, polymer, metamaterial etc. External photonics components(s) may be coupled to, for example, internal optical waveguides 144 (FIG. 1) that are optically coupled to active circuitry 104 in a known fashion. I/O opening(s) 130 can take any now known or later developed form such as but not limited to: V-groove(s), U-grooves, inverse taper, trident, or any other trench groove, etc. While described relative to a PIC chip, it will be recognized that the teachings of the disclosure are applicable to any IC chip having adjacent I/O openings 130 separated by respective walls 140.

To prevent moisture ingress, structure 100 includes a moisture barrier 160 surrounding active circuitry 104. For example, moisture barrier 160 may extend around an exterior of IC chip 101. As shown in FIGS. 1 and 2, moisture barrier 160 is also on inner surfaces of each I/O opening 130. More particularly, moisture barrier 160 may be on inner endwalls 166 and opposing axial sidewalls 170 of I/O openings 130, and corners 168 where inner endwalls 166 and opposing axial sidewalls 170 meet. As will be further described, moisture barrier 160 may also be on outer surfaces 152 of metal finger structure 150 (hereafter “finger structure 150” for brevity). Moisture barrier 160 may include any now known or later developed barrier configured to resist, and ideally prevent, moisture ingress. Moisture barrier 160 may include one or more layers of dielectric. For example, moisture barrier 160 may include but is not limited to one or more vertically arranged, elongated members of dielectric positioned in one or more ILDs of interconnect layers 118 (FIGS. 2-3). In one non-limiting example, shown in FIGS. 2 and 3, moisture barrier 160 may include one or more silicon nitride or other moisture impervious dielectric material layers 162 surrounded by a dielectric layer 164, e.g., an interlayer dielectric such as a low dielectric constant material. Dielectric layer 164 may be part of any of interconnect layers 118. Each dielectric layer 164 of interconnect layers 118 may be separated by a cap layer (shown in some of the drawings but no all for clarity). In some areas, moisture barrier 160 includes a silicon nitride or other moisture impervious dielectric material layer 162 on an inner surface of I/O opening(s) 130 (and outer surfaces 152 of finger structure 150). In other areas, moisture barrier 160 includes a pair of silicon nitride or other moisture impervious dielectric material layer 162 (hereafter “MB layer 162” for brevity) separated by dielectric layer 165, e.g., of a silicon oxide. Moisture barrier 160 may have the latter format where, for example, it extends around an entirety of IC chip 101, i.e., outside of I/O openings 130 (see e.g., FIG. 1). Hence, in certain embodiments, moisture barrier 160 may include one or more MB layers 162, e.g., of silicon nitride. Further, each I/O opening 130 may include dielectric layer 165, e.g., a silicon oxide, therein. Hence, in certain embodiments, moisture barrier 160 includes an MB layer 162, and I/O opening 130 includes dielectric layer 165 surrounding finger structure 150. Other forms of moisture barrier 160 are also possible. Moisture barrier 160 can be formed using any now known or later developed semiconductor fabrication techniques.

Structure 100 may also include a metal guard ring 180 (hereafter “guard ring 180”). Guard ring 180 may include any now known or later developed layered metal elements coupled to ground to electrically isolate active circuitry 104 and other components of structure 100 from, among other things, electrical interference. Guard ring 180 may extend around an exterior of IC chip 101. More particularly, as shown in FIG. 3, metal guard ring 180 may extend vertically over at least one via layer 184 and at least one metal wire layer 186 of IC chip 101, i.e., as it extends around the exterior of IC chip 101. Via layer(s) 184 and metal layer(s) 186 are part interconnect layers 118. The metal of vias and metal wires in layers 184, 186, respectively, may be surrounded by any dielectric layer 164 used for interconnect layers 118, e.g., a low-k dielectric material. Guard ring 180 can start in any interconnect layer 118. In certain embodiments, a lowermost metal layer 186 may be, for example, a first metal layer M1 of IC chip 101, and a lowermost via layer 184 may be, for example, a zero via layer V0 of IC chip 101. Vias in via layer(s) 184 may include a plurality of discrete vias 188 (FIGS. 2-3) separated by dielectric layer 164, or trench vias 190 (FIG. 3) that are one piece within dielectric layer 164. As shown in FIG. 1, where provided, guard ring 180 may extend around an entirety of IC chip 101 and be positioned internally of moisture barrier 160.

In certain embodiments, shown in FIG. 1 structure 100 may also include one or more crack stops 200 that is within and/or surrounds moisture barrier 160 (and guard ring 180) to prevent cracking and/or unwanted stress in IC chip 101 or in moisture barrier 160 that could lead to moisture ingress. Crack stop(s) 200 may include any now known or later developed layered conductive elements. Guard ring 180 and crack stop 200 can be in any interconnect layers 118 and can be formed using any now known or later developed semiconductor fabrication techniques.

Moisture barrier 160 is subject to damage where, for example, inner endwalls 166 of I/O openings 130 form inner corners 168 (FIG. 1 only) with opposing axial sidewalls 170 of I/O openings 130 or other surfaces. More particularly, corners 168 present areas of increased film stress susceptible to cracks or other damage to moisture barrier 160. The damage can lead to a heightened risk of moisture ingress. Crack stops 200 are also used around IC chip 101 to prevent cracks from propagating through a chip, but do not adequately address damage to moisture barriers 160.

Embodiments of the disclosure provide mechanisms to reduce and/or eliminate damage to moisture barriers 160 within I/O opening(s) 130. More particularly, structure 100 may include finger structure(s) 150 protruding partly into I/O opening(s) 130. Finger structure(s) 150 extends only partly across (side-to-side) of a respective I/O opening 130. Part of finger structure 150 may be in interconnect layers 118 outside of I/O opening 130, but part of finger structure 150 protrudes partly into I/O opening 130. As will be further described, finger structure(s) 150 are formed similarly to guard ring 180 (and thus may also be referred to as “metal finger structure” or “metal guard ring finger structure”), and have similar layered conductive vias and metal wires. As shown for example in FIG. 1, finger structure(s) 150 may be coupled to guard ring 180, and thus may be considered an extension of guard ring 180. As noted, I/O opening 130 is otherwise filled with external I/O component 142 and a dielectric layer 165, e.g., a silicon oxide. Dielectric layer 164 may include a different dielectric material than the materials of dielectric layer 164 of interconnect layers 118.

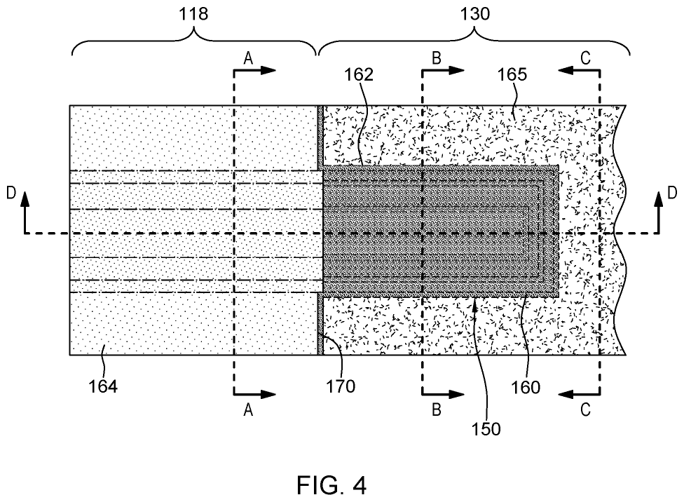

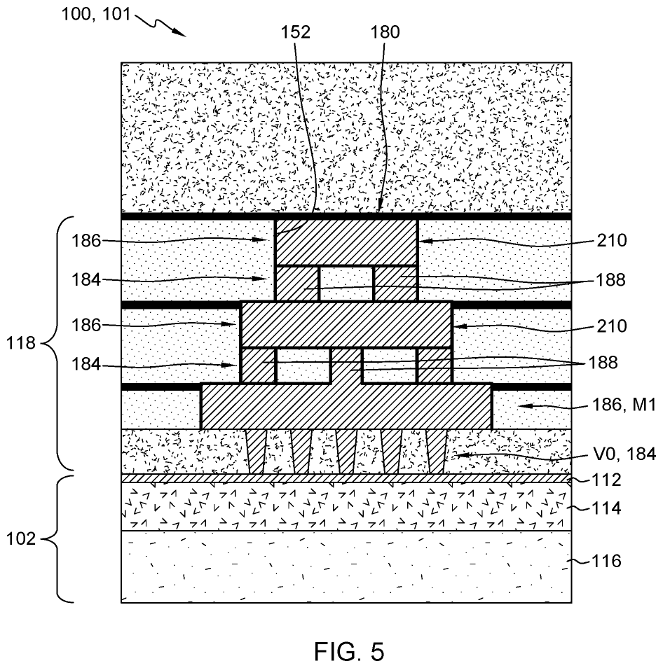

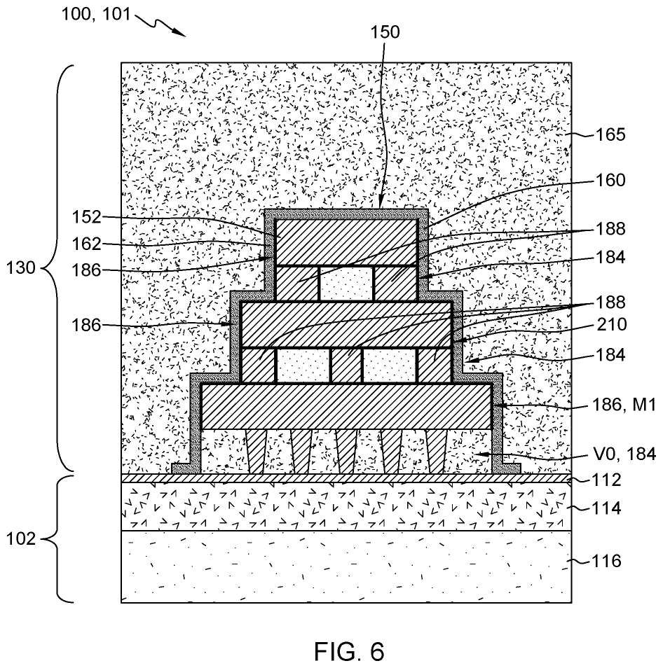

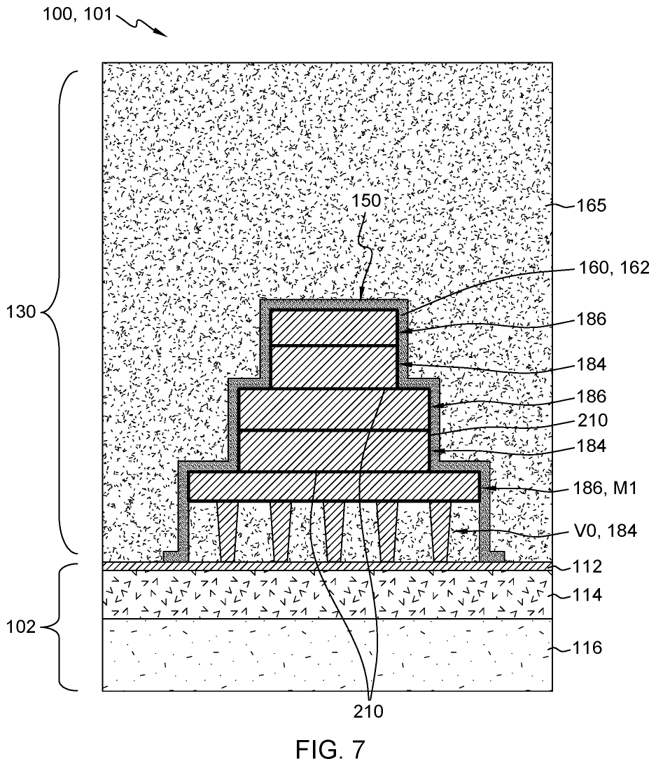

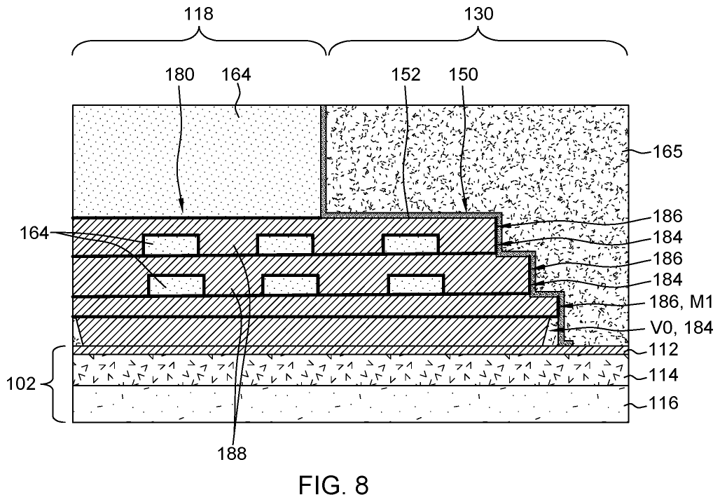

FIG. 4 shows an enlarged top-down view of finger structure 150 from the view box in FIG. 1, according to embodiments of the disclosure. FIG. 5 shows a cross-sectional view along view line A-A in FIG. 4 of finger structure 150 in interconnect layers 118, FIG. 6 shows a cross-sectional view along view line B-B in FIG. 4 of finger structure 150 in I/O opening 130, FIG. 7 shows an end view along view line C-C in FIG. 4 of finger structure 150 in I/O opening 130, and FIG. 8 shows a cross-sectional view along view line D-D in FIG. 4 of finger structure 150 in both interconnect layers 118 and I/O opening 130, according to certain embodiments of the disclosure.

As noted, finger structure(s) 150 may be formed as part of, or separately from, guard ring 180. Finger structure(s) 150 includes similar structure to guard ring 180. More particularly, finger structure(s) 150 may extend vertically over at least one via layer 184 and at least one metal wire layer 186 of IC chip 101. Via layer(s) 184 and metal layer(s) 186 of finger structure 150 are part of interconnect layers 118 and can extend, like a T, from guard ring 180. However, via layer(s) 184 and metal layer(s) 186 of finger structure 150, as shown in FIG. 3, also extend into I/O opening 130 to form finger structure 150. Vias and metal wires in layers 184, 186, respectively, in I/O opening 130 may be surrounded by interlayer dielectric 165, e.g., a silicon oxide. Finger structure 150, like guard ring 180, can start in any interconnect layer 118, i.e., any via or metal layer 184, 186. In certain embodiments, a lowermost metal layer 186 of finger structure 150 may be, for example, first metal layer M1 of IC chip 101, and a lowermost via layer 184 of finger structure 150 may be, for example, zero via layer V0 of IC chip 101. However, finger structure 150 can have a lower end thereof in other than those interconnect layers 118.

As shown in FIGS. 5 and 6, in certain embodiments, finger structure 150 may include a plurality of discrete vias 188 separated by dielectric layer 164 in a via layer 184. That is, at least one via layer 184 in finger structure 150 may include plurality of vias 188 separated by dielectric layer 164.

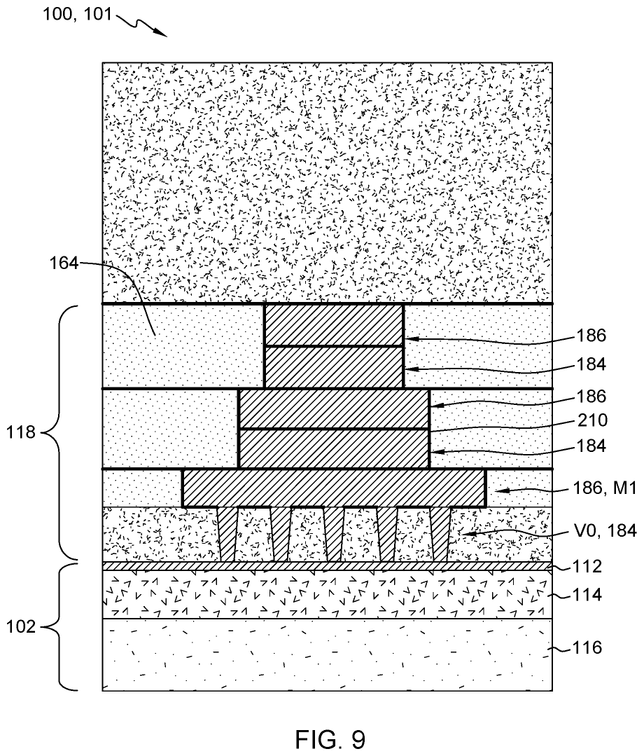

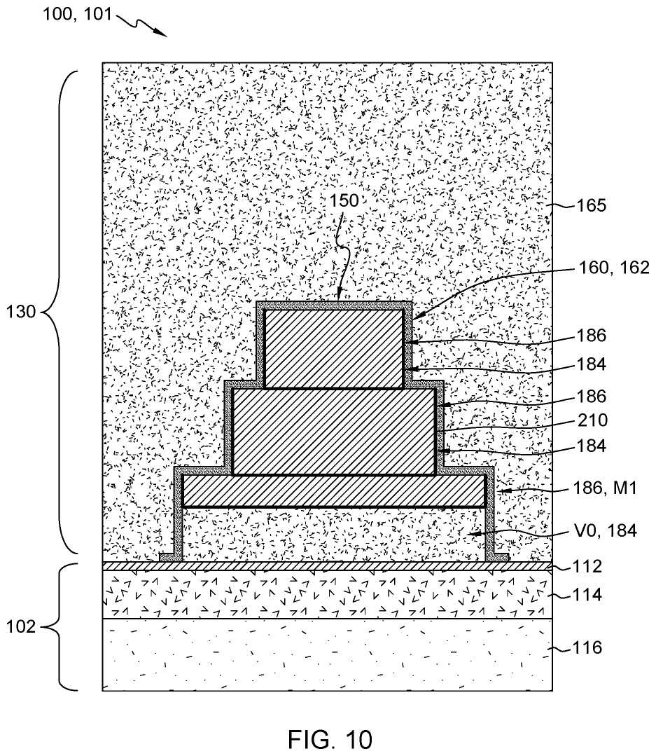

FIG. 9 shows a cross-sectional view along view line A-A in FIG. 4 of finger structure 150 in interconnect layers 118, and FIG. 10 shows a cross-sectional view along view line B-B in FIG. 4 of finger structure 150 in I/O opening 130, according to other embodiments. As shown in FIGS. 9 and 10, in an alternative embodiment, finger structure 150 may include trench vias 190 rather than discrete vias 188 (FIGS. 5-6) that are one piece within dielectric layer 164 in interconnect layers 118 (FIG. 8) or dielectric layer 165 in I/O opening 130. Here, there is no dielectric layer 164 within each via layer 184 within finger structure 150. It will be recognized that while the FIGS. 5 and 6 embodiment and the FIGS. 9 and 10 embodiment are shown separately, different via layers 184 within a single finger structure 150 can include either arrangement, such that discrete vias 188 and trench vias 190 exist in the same finger structure 150.

As shown in FIGS. 3 and 5-10, finger structure 150 may have a stair-stepped outer surface 152. More particularly, as shown in FIGS. 6, 7, 10, each via or metal layer 184, 186 of finger structure 150 is narrower in width than one or more via or metal layer 184, 186 therebelow, creating a stair-stepped outer surface 152 in a width-wise direction. Similarly, as shown in FIGS. 3 and 8, each via or metal layer 184, 186 of finger structure 150 is shorter in length than one or more via or metal layer 184, 186 therebelow, creating a stair-stepped outer surface 152 in a length-wise direction. The stair-stepped outer surface 152 may have some variation from uniform steps in terms of length, width and/or height, as would be expected within semiconductor fabrication tolerances. Stair-stepped outer surface 152 aids in reducing attacking surfaces for stress, which may reduce the likelihood of damage caused by stress.

Structure 100 also includes outer surfaces 152 of finger structure 150 covered by moisture barrier 160, i.e., in I/O opening(s) 130. Outer surface 152 of finger structure 150 in I/O opening 130 may include moisture barrier 160 in the form of a MB layer 162, e.g., a silicon nitride layer. Each I/O opening 130 may include dielectric layer 165, e.g., a silicon oxide, over moisture barrier 160 over outer surfaces 152 of finger structure 150. Other forms of moisture barrier 160 are also possible. Finger structure 150 is formed like guard ring 180 in that its via and metal layers 184, 186 may be formed by etching openings into dielectric layer 164, and depositing metal therein, e.g., by chemical vapor deposition. The metal deposited may include a refractory metal liner 210 (e.g., ruthenium, tantalum (Ta), tantalum nitride (TaN), titanium (Ti), tungsten (W), iridium (Ir), rhodium (Rh) and platinum (Pt), etc., or mixtures of thereof such as Ta/TaN) followed by any via/wire conductive metal such as copper or copper alloys (e.g., CuMn), tungsten or aluminum. When I/O opening 130 is formed, it exposes layers 184, 186 and refractory metal liner 210 on at least sidewalls of finger structure 150. Hence, while moisture barrier 160 deposited in I/O opening 130 after exposure of layers 184, 186 of finger structure 150 covers outer surfaces 152, it may also cover the via/wire conductive metal or refractory metal liner 210 (latter on at least sidewalls of finger structure 150). (Note, not all refractory metal liner locations are shown (e.g., with thicker lines) for clarity purposes.) In contrast, the part of finger structure 150 that is in interconnect layers 118 is not exposed by formation of I/O opening 130. Hence, moisture barrier 160 is not present because dielectric layer 164 of interconnect layers 118 covers whatever part of finger structure 150 is in interconnect layers 118.

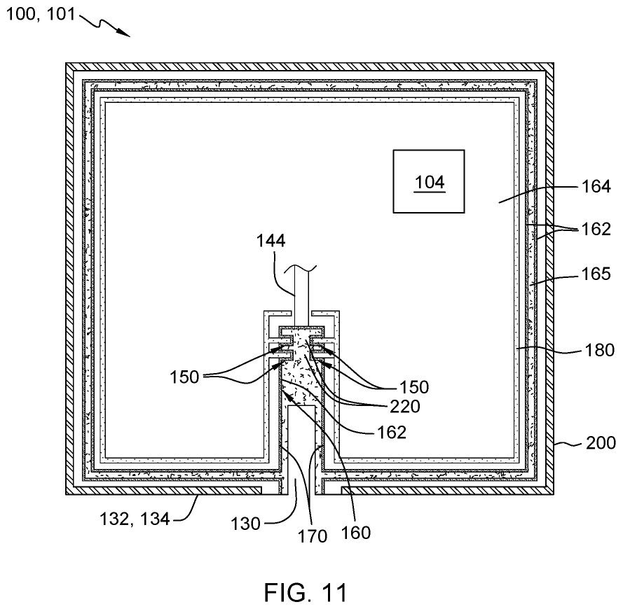

FIGS. 11-13 show top-down views of structure 100 and IC chip 101 including finger structure(s) 150 according to alternative embodiments. Any number of finger structures 150 can be used within structure 100 and IC chip 101, and within a given I/O opening 130. More specifically, finger structure(s) 150 can have a large variety arrangement configured to, for example, relieve stress on moisture barrier 160. In certain embodiments, structure 100 includes at least one pair of opposing finger structures 150 protruding partly into I/O opening from opposing sides, e.g., sidewalls 170, of I/O opening 130. In FIGS. 1 and 3, a single pair of finger structures 150 are shown in I/O opening 130. In an alternative embodiment, shown in a top-down view in FIG. 11, two pairs of finger structures 150 are shown in I/O opening 130. In FIG. 11, each finger structure 150 protrudes partly into I/O opening from a given sidewall 170 of I/O opening 130 opposite another finger structure 150 protruding partly into I/O opening 130 from an opposing sidewall 170 of I/O opening 130. More than two pairs of finger structures 150 may also be possible within a given I/O opening 130. That is, at least two pairs of opposing finger structures 150 may protrude partly into an I/O opening 130. As shown in FIG. 3, in any arrangement in which opposing finger structures 150 are used, each pair of finger structures 150 have a space 220 between opposing ends 222 thereof. In this manner, either external component 142 or an optical signal from external component 142 can pass through space 220 (via dielectric layer 165) to other internal structure such as silicon edge coupler 120 and/or internal optical waveguides 144 (FIG. 1) that are optically coupled to active circuitry 104 in a known fashion.

In another embodiment, shown in a top-down view in FIG. 12, more than one I/O opening 130 is used. That is, I/O opening 130 includes more than one I/O opening 130 spaced within IC chip 101. In this example, two I/O openings 130A, 130B are adjacent one another with wall 140 therebetween. While FIG. 12 shows two I/O openings 130A, 130B, more than two are also possible. In any event, each I/O opening 130A, 130B includes a respective finger structure 150 protruding partly therein. In FIG. 12, each I/O opening 130A, 130B includes a single finger structure 150 protruding partially therein. FIG. 13 shows a top-down view of structure 100 with two I/O openings 130A, 130B each including a single pair of finger structures 150 protruding partially therein. In FIGS. 12 and 13, no opposing finger elements 150 are present (and guard ring 180 is not present in wall 140).

While the drawings show various discrete arrangements of I/O openings 130 and finger structures 150, the various arrangements illustrated can be intermixed in any manner.

A method according to embodiments of the disclosure will now be described. As those with ordinary skill in the art are knowledgeable of the individual processes used in the method, no detailed drawings are necessary for understanding. Embodiments of the method may include forming a metal guard ring 180 extending around an exterior of substrate 102 of IC) chip 101, including forming a metal guard ring finger structure 150 coupled to metal guard ring 180. Forming a metal guard ring extending around an exterior of a substrate of an integrated circuit (IC) chip, including forming a metal guard ring finger structure 150 coupled to the metal guard ring 180. As noted, metal finger structure 150 eventually protrudes partly into I/O opening 130. Metal guard ring 180 and finger structure 150 may be formed using any now known or later developed MOL or BEOL fabrication techniques, such as but not limited to damascene or dual damascene processes. As understood by those with skill in the art, damascene processing includes depositing a dielectric layer (e.g., layer 164), lithographically defining openings (for vertical vias or trench vias and/or horizontal wires) in the dielectric layer (e.g., by using a patterned mask and etching) and then depositing metal (refractory metal liner then via/wire metal) to fill the resulting openings. Dual damascene means the openings for vias and metal wires are formed vertically at the same time, and the metal deposition fills the vertically contiguous via and metal wire openings. In any case, excess metal is removed by planarization, such as chemical-mechanical polishing. The process is repeated for as many interconnect layers 118 as desired to form guard ring 180 and/or finger structure 150.

The method may also include forming I/O opening 130 extending inwardly from exterior surface 132 of IC chip 101 such that finger structure 150 protrudes partly into I/O opening 130. I/O opening(s) 130 may be formed by lithographically defining the openings in dielectric layers 164 of interconnect layers 118, e.g., forming a patterned mask and etching. This process forms I/O opening(s) 130 and exposes the part of finger structure(s) 150 that is/are to protrude into I/O opening(s) 130.

The method may also include forming moisture barrier 160 (actually MB layer 162) over outer surfaces 152 of finger structure 150, e.g., by chemical vapor deposition of a impervious dielectric material such as silicon nitride. Moisture barrier 160 may also be formed to extend around the exterior of substrate 102 of IC chip 101 adjacent metal guard ring 180. In this case, a trench may be formed in the desired layout prior to depositing a layer of the moisture impervious dielectric material in the trench to form MB layers 162, e.g., by using a patterned mask and etching. Dielectric layer 165, e.g., a silicon oxide, is deposited to fill the rest of the trench, and a planarization performed to remove excess material. In this manner, moisture barrier 160 includes just MB layer 162 over outer surface 152 of finger structure in I/O opening 130, and two MB layers 162 separated by dielectric layer 165 around the exterior of substrate 102 of IC chip 101. The deposition of dielectric layer 165 to form moisture barrier 160 around the exterior of substrate 102 of IC chip 101 would also fill the balance of I/O opening 130 that is not filled by finger structure 150 or external component 142.

Embodiments of the disclosure provide various technical and commercial advantages, examples of which are discussed herein. The structure improves IC chip moisture barrier robustness. As described, the finger structure may reduce film stresses in the I/O openings, reducing the likelihood of damage to the moisture barrier.

The structure and method as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure, comprising:
an integrated circuit (IC) chip including a substrate;
an input/output (I/O) opening extending inwardly from an exterior surface of the IC chip; and
a metal finger structure protruding partly into the I/O opening, wherein outer surfaces of the metal finger structure are covered by a moisture barrier.

2. The structure of claim 1, wherein the metal finger structure has a stair-stepped outer surface.

3. The structure of claim 1, wherein the metal finger structure extends vertically over at least one via layer and at least one metal wire layer of the IC chip.

4. The structure of claim 3, wherein the at least one via layer includes a plurality of vias separated by a dielectric layer.

5. The structure of claim 1, wherein the moisture barrier covers a refractory metal liner on at least sidewalls of the metal finger structure.

6. The structure of claim 1, wherein the metal finger structure protruding partly into the I/O opening includes at least one pair of opposing metal finger structures protruding partly into the I/O opening from opposing sides of the I/O opening, each pair of metal finger structures having a space between opposing ends thereof.

7. The structure of claim 6, wherein the at least one pair of opposing metal finger structures protruding partly into the I/O opening includes at least two pairs of opposing metal finger structures protruding partly into the I/O opening.

8. The structure of claim 1, wherein the I/O opening includes more than one I/O opening spaced within the IC chip, each I/O opening including a respective metal finger structure protruding partly into a respective I/O opening.

9. The structure of claim 1, wherein the moisture barrier is also on inner surfaces of the I/O opening.

10. The structure of claim 1, wherein the moisture barrier also extends around an exterior of the IC chip.

11. The structure of claim 1, further comprising a metal guard ring extending around an exterior of the IC chip, where in the metal finger structure is coupled to the metal guard ring.

12. The structure of claim 1, wherein the exterior surface includes an edge of the IC chip.

13. The structure of claim 1, wherein the moisture barrier includes a silicon nitride layer, and the I/O opening includes an oxide surrounding the metal finger structure.

14. A structure, comprising:
an integrated circuit (IC) chip including a substrate;
an input/output (I/O) opening extending inwardly from an exterior surface of the IC chip;
a metal guard ring extending around an exterior of the substrate; and
a metal guard ring finger structure coupled to the metal guard ring and protruding partly into the I/O opening and extending vertically over at least one via layer and at least one metal wire layer of the IC chip,
wherein outer surfaces of the metal guard ring finger structure are covered by a moisture barrier,
wherein the metal guard ring finger structure has a stair-stepped outer surface.

15. The structure of claim 14, wherein the at least one via layer includes a plurality of vias separated by a dielectric layer.

16. The structure of claim 14, wherein the metal guard ring finger structure protruding partly into the I/O opening includes at least one pair of opposing metal guard ring finger structures protruding partly into the I/O opening from opposing sides of the I/O opening, each pair of metal guard ring finger structures having a space between opposing ends thereof.

17. The structure of claim 16, wherein the at least one pair of opposing metal guard ring finger structures protruding partly into the I/O opening includes at least two pairs of opposing metal guard ring finger structures protruding partly into the I/O opening.

18. The structure of claim 14, wherein the moisture barrier is also on inner surfaces of the I/O opening and extends around an exterior of the IC chip.

19. The structure of claim 14, wherein the moisture barrier includes a silicon nitride layer, and the I/O opening includes an oxide surrounding the metal guard ring finger structure.

20. A method, comprising:
forming a metal guard ring extending around an exterior of a substrate of an integrated circuit (IC) chip, including forming a metal guard ring finger structure coupled to the metal guard ring, wherein the metal guard ring finger structure protrudes partly into an input/output opening; and
forming a moisture barrier over outer surfaces of the metal guard ring finger structure and extending around the exterior of the substrate of the IC chip adjacent the metal guard ring.
